(19) United States
(12) Patent Application Publication
(10) Pub. No.: US 2026/0313838 A1
(43) Pub. Date: Oct. 8, 2026

(54) COOLING AND ENERGY RECOVERY SYSTEM FOR DATA CENTER SERVER COMPUTERS

(71) Applicant: Jason Todd Roth, Orlando, FL (US)

(72) Inventor: Jason Todd Roth, Orlando, FL (US)

(21) Appl. No.: 19/639,468

(22) Filed: Apr. 6, 2026

Related U.S. Application Data
(60) Provisional application No. 63/785,362, filed on Apr. 8, 2025.

(51) Int. Cl. H05K 7/20; G06F 1/20

(52) U.S. Cl. CPC H05K 7/20272; G06F 1/20; H05K 7/20781

(57) ABSTRACT

A cooling and energy recovery system for electronic equipment includes a sealed server chassis and a dual-pipe heat exchanger fluidly coupled to the sealed server chassis by an exhaust pipe and a supply pipe. The dual-pipe heat exchanger includes an inner pipe and an outer pipe defining an annular space therebetween. Gas heated by electronic equipment circulates from the sealed server chassis through the inner pipe and back to the sealed server chassis. Nitrogen circulating through the annular space absorbs heat from the gas flowing through the inner pipe. An inner screw turbine disposed within the inner pipe rotates in response to flow of the gas and is coupled to a generator. An outer turbine disposed within the annular space rotates in response to flow and expansion of the nitrogen. In some embodiments, magnetic levitation assemblies support the turbines.

### CROSS-REFERENCE TO RELATED APPLICATIONS

This application is based upon U.S. provisional Application No. 63/785,362 filed Apr. 8, 2025, the disclosure which is hereby incorporated by reference in its entirety.

### TECHNICAL FIELD

The present disclosure relates generally to cooling and energy recovery systems for electronic equipment and, more particularly, to sealed nitrogen-based cooling and energy recovery systems for data center server computers and other heat-generating electronic equipment.

### BACKGROUND

Cooling data center server computers presents a significant challenge because the servers often run continuously and generate substantial amounts of heat. If the heat is not properly managed, overheating can occur, which may reduce performance, impair reliability, and lead to hardware failure. Cooling systems can also consume large amounts of power, thereby increasing operational costs and reducing overall facility efficiency.

Heat distribution within a data center is often uneven, which can create localized hot spots. In addition, inefficient airflow caused by rack arrangement, obstructed vents, inadequate containment, or limitations of room-scale air delivery can reduce cooling effectiveness. Environmental conditions within the data center can also affect reliability. For example, excessive humidity can contribute to condensation and corrosion, while insufficient humidity can contribute to electrostatic discharge or other undesirable conditions that may affect sensitive electronic components.

As data centers grow in size, server density, and compute intensity, cooling requirements increase accordingly. However, space limitations can make it difficult to install or expand conventional cooling infrastructure. Traditional cooling approaches, such as room-scale air conditioning, chilled air systems, evaporative cooling systems, and liquid-cooling systems, can require substantial infrastructure, energy consumption, maintenance, and, in some cases, significant water usage. In addition, increasing server density may require extensive facility upgrades in order for such cooling approaches to remain effective.

Conventional cooling environments may also expose server hardware to conditions that contribute to degradation over time. Oxidation, corrosion, condensation, particulate contamination, and repeated thermal cycling can reduce the useful life of electronic components and increase maintenance, downtime, and replacement costs. These concerns can become more pronounced in high-density computing installations and in environments having elevated moisture, airborne contaminants, or other adverse air-quality conditions.

Modern compute environments, including installations supporting artificial intelligence, GPU clusters, and other high-performance workloads, further increase cooling demands. Such environments can generate elevated thermal loads and can place additional strain on conventional air-cooled and liquid-cooled architectures. In some cases, conventional cooling approaches may also present challenges relating to water consumption, mechanical complexity, and limited scalability, particularly where vertical expansion, modular deployment, or high-density installation is desired.

Accordingly, what is needed in the art is an improved cooling system for electronic equipment, such as data center server computers, that reduces cooling energy demand, improves cooling efficiency, reduces dependence on conventional water-based cooling infrastructure, mitigates hardware degradation associated with conventional cooling environments, and is scalable for higher density and larger scale deployments.

### SUMMARY

In one aspect, the present disclosure provides a cooling and energy recovery system for electronic equipment. The system includes a sealed server chassis configured to house electronic equipment including one or more heat-generating components, an exhaust pipe and a supply pipe fluidly coupled to the sealed server chassis, and a dual-pipe heat exchanger comprising an inner pipe and an outer pipe disposed radially outward of the inner pipe. The outer pipe and the inner pipe define an annular space therebetween. The inner pipe has an inlet fluidly coupled to the exhaust pipe and an outlet fluidly coupled to the supply pipe such that gas heated by the electronic equipment circulates from the sealed server chassis, through the inner pipe, and back to the sealed server chassis in a closed-loop or substantially closed-loop flow path. Nitrogen circulates through the annular space and is configured to absorb heat from the gas flowing through the inner pipe. An inner screw turbine is disposed within the inner pipe and is configured to rotate in response to flow of the gas through the inner pipe. A generator coupling is operatively coupled to the inner screw turbine, and a first electrical generator is directly or indirectly operatively associated with the generator coupling and is configured to generate electrical energy from rotation of the inner screw turbine. An outer turbine is disposed within the annular space and is configured to rotate in response to flow of the nitrogen circulating through the annular space and expansion of the nitrogen within the annular space.

In some embodiments, the sealed server chassis is configured to define a pressure-maintainable enclosure. In some embodiments, the gas circulating through the sealed server chassis, the exhaust pipe, the inner pipe, and the supply pipe comprises nitrogen or a nitrogen-rich gas. In some embodiments, the system further includes an inner magnetic levitation assembly configured to levitate, center, support, and/or stabilize the inner screw turbine within the inner pipe. In some embodiments, the inner magnetic levitation assembly comprises one or more permanent magnets, Halbach arrays, passive magnetic bearings, active magnetic bearings, electromagnets, hybrid magnetic supports, or combinations thereof. In some embodiments, the system further includes an outer magnetic levitation assembly configured to magnetically support and stabilize the outer turbine relative to the inner pipe, the outer pipe, or both. In some embodiments, the inner pipe includes a conductive wall configured to transfer heat from the gas flowing through the inner pipe to the nitrogen circulating through the annular space.

In some embodiments, the system further includes at least one cryogenic nitrogen injector configured to introduce gaseous nitrogen, liquid nitrogen, or a mixed-phase nitrogen flow into the annular space. In some embodiments, the system further includes a controller configured to control operation of the at least one cryogenic nitrogen injector and to regulate circulation of the nitrogen through the annular space based on at least one sensed operating condition. In some embodiments, the at least one sensed operating condition comprises at least one of temperature, pressure, flow rate, humidity, oxygen concentration, gas composition, vibration, electrical current, or leak detection. In some embodiments, the system further includes a pressure relief valve configured to prevent over-pressurization of at least one of the sealed server chassis, the dual-pipe heat exchanger, the annular space, the supply pipe, or the exhaust pipe. In some embodiments, the sealed server chassis is configured to operate without conventional internal mechanical fans.

In another aspect, the present disclosure provides a cooling chassis assembly for electronic equipment. The cooling chassis assembly includes a sealed server chassis configured to house electronic equipment including one or more heat-generating components, an exhaust pipe configured to direct heated gas from the sealed server chassis to a dual-pipe heat exchanger, a supply pipe configured to return cooled gas from the dual-pipe heat exchanger to the sealed server chassis, at least one internal flow path configured to direct the gas over and around the one or more heat-generating components, and at least one hermetic wire pass-through configured to permit an electrical line, a control line, a data line, or an optical line to pass through a boundary of the sealed server chassis while maintaining pressure integrity of the sealed server chassis.

In some embodiments, the one or more heat-generating components comprise at least one of a CPU, a GPU, a memory module, a storage device, a power supply, or power electronics. In some embodiments, the sealed server chassis comprises a nitrogen-pathway server chassis in which an internal cooling route is integrated into a structure of the sealed server chassis. In some embodiments, the sealed server chassis comprises a containment shell configured to receive an existing server. In some embodiments, the sealed server chassis comprises a modular containment pod having pre-wired internal power and signal interfaces configured to permit insertion and removal of server hardware while maintaining a sealed cooling environment.

In a further aspect, the present disclosure provides a method of cooling electronic equipment and recovering energy therefrom. The method includes housing electronic equipment in a sealed server chassis, circulating gas heated by the electronic equipment from the sealed server chassis through an inner pipe of a dual-pipe heat exchanger and back to the sealed server chassis in a closed-loop or substantially closed-loop flow path, circulating nitrogen through an annular space between the inner pipe and an outer pipe of the dual-pipe heat exchanger such that heat is transferred from the gas in the inner pipe to the nitrogen in the annular space, rotating an inner screw turbine disposed within the inner pipe using flow of the gas through the inner pipe, and generating electrical energy from rotation of the inner screw turbine.

In some embodiments, the method further includes rotating an outer turbine disposed within the annular space using flow of the nitrogen in the annular space and expansion of the nitrogen within the annular space. In some embodiments, the method further includes introducing gaseous nitrogen, liquid nitrogen, or a mixed-phase nitrogen flow into the annular space with at least one cryogenic nitrogen injector based on at least one sensed operating condition.

### BRIEF DESCRIPTION OF THE DRAWINGS

The aspects and the attendant advantages of the embodiments described herein will become more readily apparent by reference to the following detailed description when taken in conjunction with the accompanying drawings wherein:

FIG. 1 is a schematic view of a cooling and energy recovery system for data center server computers in accordance with aspects of the disclosure;

FIG. 2 is a perspective partial cut-away view of an inner pipe of the dual-pipe heat exchanger of FIG. 1, showing an inner screw turbine, a generator coupling, and an inner magnetic levitation assembly;

FIG. 3 is a schematic view of airflow through a sealed server chassis or pressure box of a data center that houses server computers or other electronic equipment;

FIG. 4 is a schematic depicting counter-rotating magnetic fields of the dual-pipe heat exchanger;

FIG. 5 is a perspective partial cut-away view of an outer pipe of the dual-pipe heat exchanger of FIG. 1, showing an outer turbine, blades or fins, and an outer magnetic levitation assembly;

FIG. 6 is a graph depicting a magnetic force distribution of a Halbach cylindrical array of the dual-pipe heat exchanger 102;

FIG. 7 is a graph depicting modeled cumulative efficiency impact associated with successive features of the disclosed cooling and energy recovery system;

FIG. 8 is a table or chart depicting an example modeled energy harvest and loss profile for the disclosed cooling and energy recovery system during an operational cycle;

FIG. 9 is a graph depicting comparative annual water use associated with different data center cooling architectures, including a nitrogen-based closed-loop system in accordance with aspects of the disclosure; and

FIG. 10 is a graph depicting comparative failure-mode risk associated with different cooling environments.

### DETAILED DESCRIPTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

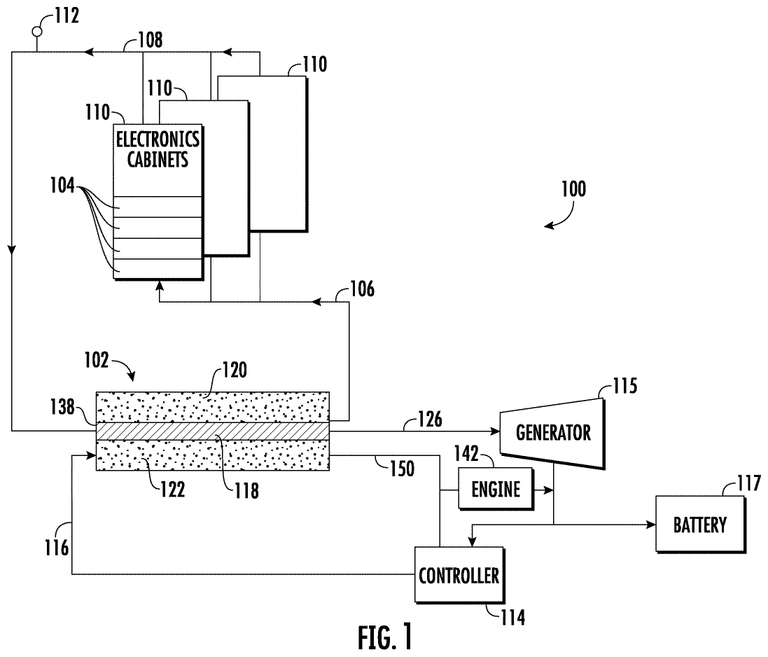

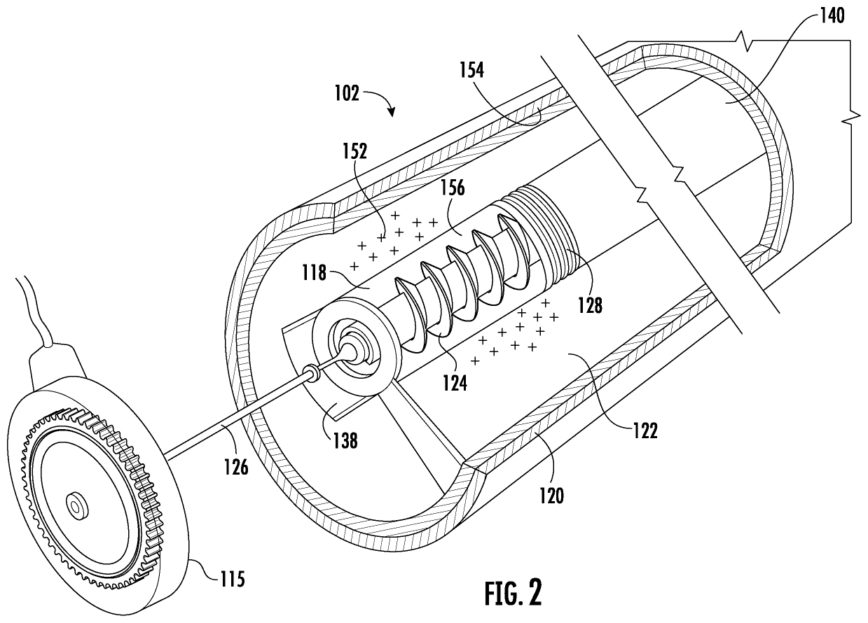

Referring initially to FIGS. 1 and 2, a cooling and energy recovery system in accordance with aspects of the disclosure is generally designated 100. In the illustrated embodiment, the system 100 is configured for use with computer equipment, server equipment, and other electronic equipment that generate heat during operation. Although described herein primarily in the context of a data center or server environment, the system 100 may also be used in other environments in which heat-generating electrical or electronic equipment is housed in an enclosure and requires thermal management, including, for example, telecommunications rooms, industrial control rooms, battery enclosures, marine electronics rooms, aerospace electronics bays, modular compute containers, edge-compute facilities, and mobile or deployable computing systems.

In the illustrated embodiment, the system 100 generally includes a dual-pipe heat exchanger 102, a sealed server chassis or pressure box 104, a supply pipe 106, an exhaust pipe 108, one or more cabinets or racks 110, a pressure relief valve 112, a controller 114, and one or more cryogenic nitrogen injectors 116. The dual-pipe heat exchanger 102 further includes an inner pipe 118, an outer pipe 120 disposed radially outwardly of the inner pipe 118, and an annular space 122 defined between the inner pipe 118 and the outer pipe 120. An inner screw turbine 124 is disposed within the inner pipe 118 and is operatively associated with a generator coupling 126 and an inner magnetic levitation assembly 128. An outer turbine 130, which may include one or more blades or fins 132, is disposed within the annular space 122 and is supported by an outer magnetic levitation assembly 134. The system 100 may further include a circulating coolant flow path, an inlet 138, an outlet 140, an optional piston power generator or Stirling engine assembly 142, one or more hermetic wire pass-throughs 144, one or more heat-generating components 148, a return line 150, magnetic fields 152, 154, a conductive wall 156, and one or more thermal expansion regions.

In general, the system 100 is configured to provide cooling to the electronic equipment 146 while also reclaiming or harvesting at least a portion of thermal energy, pressure energy, flow energy, and magnetic-induction-related energy that would otherwise be dissipated as waste heat or system loss. In one aspect, the system 100 establishes a closed or substantially closed circulation architecture in which heated gas from the sealed server chassis 104 is directed through the dual-pipe heat exchanger 102, cooled therein, and then returned to the sealed server chassis 104 for continued circulation. In one implementation, the dual-pipe heat exchanger 102 is configured to extract heat from the circulating gas while also converting fluid motion, thermal expansion, pressure differentials, and relative magnetic interaction into mechanical and/or electrical energy.

The sealed server chassis 104 is fluidly coupled to the dual-pipe heat exchanger 102 by the supply pipe 106 and the exhaust pipe 108. In one embodiment, heated gas from within the sealed server chassis 104 exits the enclosure through the exhaust pipe 108 and enters the inner pipe 118 of the dual-pipe heat exchanger 102 at the inlet 138. After heat exchange and energy recovery occur within the dual-pipe heat exchanger 102, cooled gas exits the inner pipe 118 through the outlet 140 and is returned through the supply pipe 106 to the sealed server chassis 104. This forms a closed-loop or substantially closed-loop recirculating cooling path.

In one embodiment, the circulating gas within the sealed server chassis 104, supply pipe 106, exhaust pipe 108, and inner pipe 118 comprises nitrogen or a nitrogen-rich gas. In other embodiments, another substantially inert or comparatively non-reactive gas may be used. In still further embodiments, the internal gas may comprise filtered air, a modified gas mixture, or another working fluid selected to enhance thermal performance, reduce oxidation, reduce moisture-related risks, or improve compatibility with the electronic equipment 146.

In some embodiments, the sealed server chassis 104 is positioned within a cabinet or rack 110. In other embodiments, the sealed server chassis 104 itself may define a rack-compatible housing. The cabinet or rack 110 may be a conventional cabinet modified to accommodate the sealed architecture described herein, or may be purpose-built for use with the system 100. The cabinet or rack 110 may include structural rails, mounting brackets, doors, service openings, cable management features, and manifold interfaces for the supply pipe 106 and the exhaust pipe 108.

The controller 114 may include one or more processors, control boards, microcontrollers, programmable logic devices, software modules, firmware routines, or combinations thereof. In one embodiment, the controller 114 is configured to control operation of the one or more cryogenic nitrogen injectors 116, monitor pressure levels in the sealed server chassis 104 and/or dual-pipe heat exchanger 102, regulate recirculation of coolant or gas through the circulating coolant flow path, and activate safety features such as the pressure relief valve 112. The controller 114 may also manage startup sequences, shutdown sequences, phase changes between gaseous nitrogen and liquid nitrogen, emergency venting, and energy recovery modes.

The pressure relief valve 112 is configured to prevent over-pressurization of one or more portions of the system 100. In some embodiments, the pressure relief valve 112 is coupled to the sealed server chassis 104. In other embodiments, the pressure relief valve 112 is coupled to the dual-pipe heat exchanger 102, the annular space 122, the supply pipe 106, the exhaust pipe 108, or another pressurized region. The pressure relief valve 112 may be a rupture membrane, spring-biased valve, burst disk, variable vent valve, electronically actuated valve, or another pressure release device. Multiple pressure relief devices may be provided at different pressure zones in the system 100.

In one embodiment, the one or more cryogenic nitrogen injectors 116 are configured to introduce coolant into the dual-pipe heat exchanger 102 and/or associated circulation lines. The introduced coolant may comprise gaseous nitrogen, liquid nitrogen, or a mixed-phase nitrogen flow. In one operating mode, liquid nitrogen is introduced and then expands as it absorbs heat, creating both cooling and expansion-driven rotational force. In another operating mode, cold gaseous nitrogen is circulated to provide continuous cooling with reduced phase-change intensity. In still another mode, the system 100 may transition between phases depending on thermal demand, operating mode, environmental conditions, and available nitrogen supply.

In contrast to conventional cooling systems that rely extensively on room-scale conditioned air, chilled-water loops, evaporative towers, or high-volume blower systems, the present system 100 is configured to cool electronic equipment 146 in a localized sealed environment. This can reduce the need to cool large ambient room volumes and can reduce or eliminate dependence on water-based cooling infrastructure. In some embodiments, the system 100 further reduces exposure of the electronic equipment 146 to oxygen, moisture, particulates, and contaminants, thereby reducing oxidation, corrosion, condensation, and contamination.

Referring now to FIG. 2, the inner pipe 118 of the dual-pipe heat exchanger 102 is shown in greater detail. In the illustrated embodiment, the inner pipe 118 defines a primary internal flow passage through which heated gas received from the sealed server chassis 104 travels. The inner pipe 118 includes the inlet 138 configured to receive gas from the exhaust pipe 108 and the outlet 140 configured to discharge cooled gas toward the supply pipe 106.

In one embodiment, the inner pipe 118 is cylindrical and extends along a longitudinal axis. However, the inner pipe 118 may alternatively be formed in any suitable geometry capable of providing an internal flow passage, supporting the inner screw turbine 124, and cooperating thermally with the outer pipe 120. For example, the inner pipe 118 may be straight, segmented, modular, flanged, vertically oriented, horizontally oriented, or otherwise arranged according to installation constraints.

The inner screw turbine 124 is disposed within the inner pipe 118 and is configured to rotate in response to gas flow through the inner pipe 118. In one embodiment, the inner screw turbine 124 has a helical or auger-like configuration that engages the flowing gas to convert pressure and flow velocity into rotational motion. However, the inner screw turbine 124 may take other forms, including a flanged screw, a bladed rotor, a segmented helical member, a multi-start screw, or another flow-driven rotatable member configured to be driven by gas moving through the inner pipe 118.

In one embodiment, the pitch, outer diameter, blade profile, mass distribution, and surface characteristics of the inner screw turbine 124 are selected to optimize rotational response to expected gas flow conditions. In some embodiments, the inner screw turbine 124 may be optimized for low-pressure-drop rotation. In other embodiments, the inner screw turbine 124 may be optimized for torque generation, electromagnetic interaction, or energy harvesting. In still further embodiments, multiple inner turbine sections may be disposed in series within the inner pipe 118.

The inner screw turbine 124 is supported by the inner magnetic levitation assembly 128. In one embodiment, the inner magnetic levitation assembly 128 comprises one or more magnetic structures arranged to levitate, center, support, and/or stabilize the inner screw turbine 124 within the inner pipe 118. The inner magnetic levitation assembly 128 may comprise one or more permanent magnets, Halbach arrays, passive magnetic bearings, active magnetic bearings, electromagnets, hybrid magnetic supports, or combinations thereof.

In certain embodiments, the inner magnetic levitation assembly 128 provides radial stabilization, axial stabilization, or both. In some embodiments, one or more active control elements may be used to maintain the position of the inner screw turbine 124 during operation. In other embodiments, the magnetic levitation may be substantially passive. In still other embodiments, a hybrid arrangement may be used in which magnetic support reduces loading on one or more auxiliary bearings or backup supports.

The inner screw turbine 124 is operatively coupled to the generator coupling 126. The generator coupling 126 may be directly connected to a generator 115, alternator, induction device, electrical harvesting assembly, or other energy conversion device configured to convert rotation of the inner screw turbine 124 into electrical energy. The electrical energy may be used directly to power cooling equipment 114 and/or stored in a battery 117, for example. In one embodiment, the generator coupling 126 is a shaft coupling. In other embodiments, the generator coupling 126 may comprise a magnetic coupling, a ring generator, an inductive coupling, or another transmission structure.

In one embodiment, the inner pipe 118 includes a conductive wall 156 configured to transfer heat from the gas flowing through the inner pipe 118 to coolant or fluid in the annular space 122 between the inner pipe 118 and the outer pipe 120. The conductive wall 156 may also participate in electrical conduction, charge transfer, or electromagnetic interaction. In some embodiments, the inner pipe 118 is formed of copper, copper alloy, silver-containing material, graphene composite, aluminum, multilayer conductive structure, or another material selected to provide efficient heat transfer and structural integrity.

In some embodiments, the inner pipe 118 may include internal flow-conditioning structures, vanes, baffles, liners, turbulence-inducing structures, or smooth low-friction coatings to influence the velocity profile, pressure drop, and heat transfer characteristics of the gas. In other embodiments, the inner pipe 118 may be jacketed, segmented, or provided with instrumentation ports to monitor performance.

In operation, heated gas enters the inner pipe 118 through the inlet 138 and flows along the inner pipe 118 toward the outlet 140. As the gas flows through the inner pipe 118, the gas imparts rotational force to the inner screw turbine 124, thereby causing the inner screw turbine 124 to rotate. Simultaneously, heat is transferred through the conductive wall 156 from the gas within the inner pipe 118 to the surrounding coolant environment in the annular space 122. As a result, the gas is cooled as it traverses the inner pipe 118, and the cooled gas exits at the outlet 140 for return to the sealed server chassis 104.

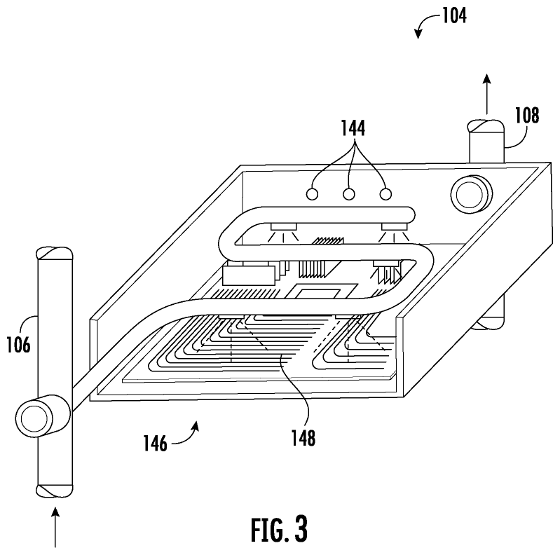

Referring now to FIG. 3, the sealed server chassis or pressure box 104 is shown schematically. The sealed server chassis 104 is configured to house one or more items of electronic equipment 146, including one or more heat-generating components 148, within a sealed or substantially sealed interior environment. In one embodiment, the sealed server chassis 104 defines a pressure-maintainable enclosure configured to contain a circulating gas while isolating the electronic equipment 146 from ambient room air.

The sealed server chassis 104 may comprise a rigid enclosure having sidewalls, a top wall, a bottom wall, front and rear access panels, one or more doors, sealing gaskets, removable service panels, and one or more mounting structures for supporting the electronic equipment 146. In some embodiments, the sealed server chassis 104 is dimensioned to receive a single server. In other embodiments, the sealed server chassis 104 may be dimensioned to receive multiple servers, blade modules, GPU trays, power supplies, networking devices, or combinations thereof.

In one embodiment, the electronic equipment 146 is arranged within the sealed server chassis 104 such that the circulating internal gas passes over and around the heat-generating components 148. The heat-generating components 148 may include CPUs, GPUs, memory modules, storage devices, power electronics, voltage regulators, interconnects, or other components that generate heat during operation. In some embodiments, the sealed server chassis 104 includes internal channels, ducts, manifolds, directional baffles, nozzles, or flow-directing walls configured to guide gas to selected high-heat regions within the enclosure.

In certain embodiments, conventional internal fans are omitted from the sealed server chassis 104, such that internal circulation is driven primarily by pressure differentials, convection, density variation, pump-assisted circulation, injector-assisted circulation, or pressure established elsewhere in the system 100. In other embodiments, one or more internal flow-assist devices may be included, although preferably at a reduced number or reduced load relative to conventional server cooling systems.

The sealed server chassis 104 can include one or more hermetic wire pass-throughs 144 configured to permit electrical conductors, communication lines, optical lines, control lines, or sensor lines to pass through the boundary of the sealed server chassis 104 while maintaining pressure integrity. The hermetic wire pass-throughs 144 may take the form of sealed glands, compression fittings, fused feedthroughs, welded feedthroughs, bulkhead connectors, modular sealed connector blocks, or other sealed penetrations.

In some embodiments, the sealed server chassis 104 further includes one or more sensors configured to monitor internal environmental parameters. Such sensors may include temperature sensors, pressure sensors, humidity sensors, oxygen sensors, gas composition sensors, flow sensors, vibration sensors, electrical current sensors, leak sensors, and other diagnostic devices. Signals from these sensors may be provided to the controller 114, which can use the sensed conditions to regulate injector flow, recirculation rate, pressure relief, safety shutoff functions, and energy recovery operating modes.

In one embodiment, the sealed server chassis 104 can take the form of a purpose-built nitrogen-pathway server chassis in which the internal cooling route is integrated into the structure of the chassis. In another embodiment, the sealed server chassis 104 can take the form of a containment shell into which a conventional server is placed. In yet another embodiment, the sealed server chassis 104 can take the form of a modular containment pod having pre-wired internal power and signal interfaces that permit rapid insertion and removal of server hardware while maintaining a sealed cooling environment.

In some embodiments, the sealed server chassis 104 is configured to maintain a relatively low-oxygen, low-moisture, and low-particulate environment around the electronic equipment 146. Such an environment can reduce oxidation, reduce corrosion, reduce condensation risk, reduce particulate contamination, and extend hardware life relative to conventional ambient-air-cooled environments.

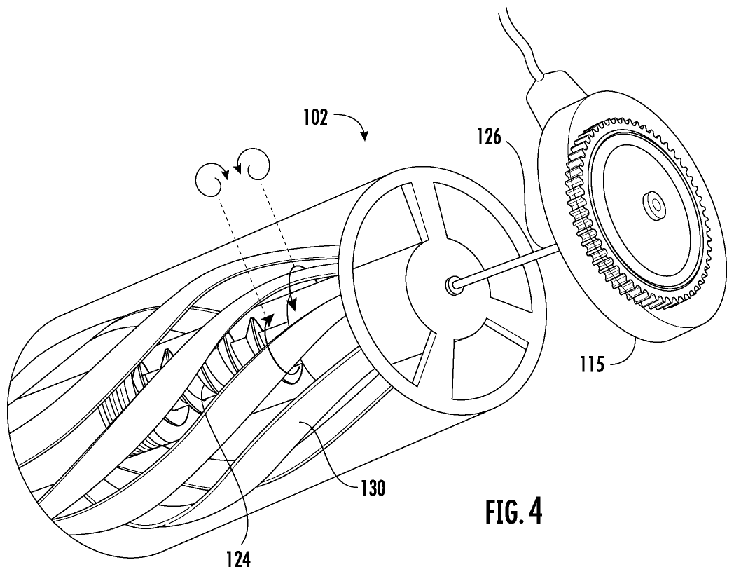

Referring now to FIG. 4, counter-rotating magnetic fields associated with the dual-pipe heat exchanger 102 are schematically illustrated. In one embodiment, the inner screw turbine 124 and the outer turbine 130 are each associated with magnetic structures configured to generate the magnetic fields 152, 154. These magnetic fields 152, 154 may be generated by permanent magnets, Halbach arrays, electromagnets, magnetized structural members, or other magnetic elements carried by or associated with the rotating structures.

In one embodiment, the inner screw turbine 124 rotates in a first rotational direction and the outer turbine 130 rotates in a second rotational direction opposite the first rotational direction. As a result, the associated magnetic fields 152, 154 also move relative to one another in opposite directions. This relative magnetic movement can increase the rate of magnetic flux change experienced by adjacent conductive or inductive structures and thereby enhance electromagnetic induction and electrical generation.

In some embodiments, the counter-rotating magnetic fields 152, 154 are used primarily to support electrical generation. In other embodiments, the magnetic interaction may additionally or alternatively be used for levitation, stabilization, synchronization, torque transfer, damping, rotational control, or regenerative braking. In certain embodiments, the same magnetic structures may serve both support and power-generation functions.

In one embodiment, the magnetic elements are arranged in a Halbach configuration to direct magnetic flux preferentially inward or outward, thereby intensifying magnetic field strength in selected regions while reducing stray flux in other regions. Such arrangements may improve levitation efficiency, reduce losses, and enhance induction performance. However, other magnetic layouts may also be used.

In some embodiments, electrical coils, induction windings, conductive rings, or generator elements may be positioned adjacent the counter-rotating magnetic fields 152, 154 such that relative movement between the magnetic fields and the conductive elements produces electrical current. The generated current may be routed to storage devices, local loads, power conditioning electronics, or other system components.

Referring now to FIG. 5, the outer pipe 120 is shown in greater detail. In the illustrated embodiment, the outer pipe 120 is disposed radially outward of the inner pipe 118 such that the annular space 122 is defined therebetween. In one embodiment, the annular space 122 serves as a secondary flow path for a nitrogen-based coolant or other selected working fluid.

In one embodiment, the outer turbine 130 is disposed within the annular space 122. The outer turbine 130 may be annular, ring-shaped, cylindrical, segmented, or otherwise configured to rotate within the annular space 122. The outer turbine 130 includes one or more blades or fins 132 configured to engage the flowing or expanding coolant within the annular space 122. As coolant moves through the annular space 122, the coolant imparts force to the blades or fins 132, thereby causing the outer turbine 130 to rotate.

The outer turbine 130 is supported by the outer magnetic levitation assembly 134. In one embodiment, the outer magnetic levitation assembly 134 magnetically supports and stabilizes the outer turbine 130 relative to the inner pipe 118, the outer pipe 120, or both. As with the inner magnetic levitation assembly 128, the outer magnetic levitation assembly 134 may include permanent magnets, Halbach arrays, passive magnetic bearings, active magnetic bearings, electromagnets, or hybrid magnetic support structures.

In one embodiment, one or more cryogenic nitrogen injectors 116 are configured to introduce coolant into the annular space 122. The introduced coolant may comprise gaseous nitrogen, liquid nitrogen, or a mixed-phase nitrogen flow. In one operating mode, liquid nitrogen is introduced and then expands as it absorbs heat, creating both cooling and expansion-driven rotational force. In another operating mode, cold gaseous nitrogen is circulated through the annular space 122 to provide continuous cooling with reduced phase-change intensity. In still another mode, the system may switch between phases depending on demand.

The coolant moving through the annular space 122 defines the circulating coolant flow path. As the coolant traverses the annular space 122, it receives heat conducted through the conductive wall 156 of the inner pipe 118 from the hotter gas flowing within the inner pipe 118. This heat transfer cools the gas in the inner pipe 118 and raises the temperature and/or expands the coolant in the annular space 122.

In one embodiment, a thermal expansion region is formed within the annular space 122 in which the coolant undergoes expansion sufficient to impart rotational force to the outer turbine 130. This expansion may be continuous, staged, pulsed, or otherwise controlled. In some embodiments, the geometry of the annular space 122, the placement of the cryogenic nitrogen injectors 116, and the blade configuration of the outer turbine 130 are selected to optimize conversion of thermal expansion into rotational energy.

In certain embodiments, the coolant circulating through the annular space 122 is maintained in a closed or substantially closed loop. The coolant may then be recaptured, reconditioned, re-compressed, phase-adjusted, or redirected through the return line 150 or a related recirculation path. In some embodiments, a portion of the pressure energy associated with coolant expansion may also be directed to the optional piston power generator or Stirling engine assembly 142 for further energy recovery.

In one embodiment, the outer pipe 120 provides a pressure-containing structure surrounding the annular space 122 and the outer turbine 130. The outer pipe 120 may be formed of metal, alloy, composite, or layered structural materials selected for pressure resistance, thermal compatibility, and magnetic integration. The outer pipe 120 may be segmented or modular and may include ports, sensors, injector mounts, service interfaces, and structural supports.

In one embodiment, the system 100 is configured such that heated gas moving through the inner pipe 118 rotates the inner screw turbine 124, while expanding nitrogen moving through the annular space 122 rotates the outer turbine 130. In this manner, the dual-pipe heat exchanger 102 can simultaneously perform multiple functions, including heat exchange, fluid-driven mechanical energy generation, and electromagnetic or generator-based electrical energy recovery.

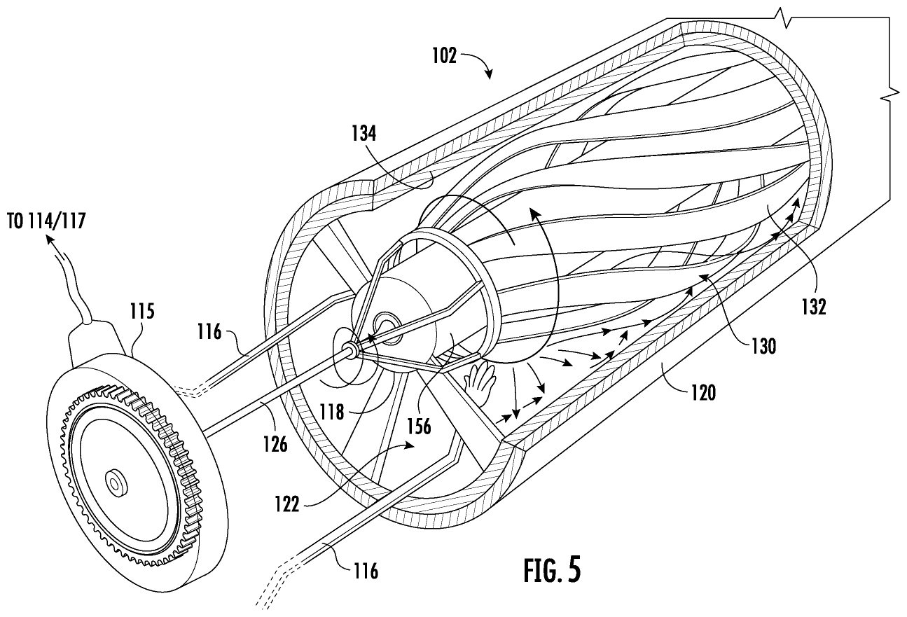

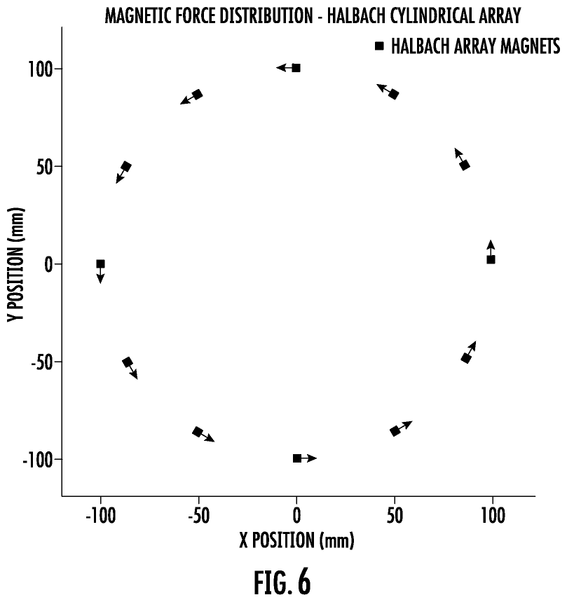

Referring now to FIG. 6, a graph is shown depicting a magnetic force distribution associated with a Halbach cylindrical array or other magnetic arrangement used in the dual-pipe heat exchanger 102. In one embodiment, the graph represents the manner in which magnetic force is concentrated in selected regions to provide enhanced levitation support, enhanced rotational stability, enhanced induction performance, or combinations thereof.

In one embodiment, the magnetic force distribution shown in FIG. 6 corresponds to a magnetic arrangement used in the inner magnetic levitation assembly 128, the outer magnetic levitation assembly 134, or both. A Halbach arrangement may be used to strengthen the magnetic field on one side of an array while reducing field intensity on the opposite side. This can improve levitation efficiency, reduce unwanted stray magnetic flux, and improve the interaction between rotating magnetic elements and adjacent conductive or inductive structures.

In some embodiments, the force distribution represented in FIG. 6 may also be selected to improve centering of the inner screw turbine 124 within the inner pipe 118, centering of the outer turbine 130 within the annular space 122, or both. In other embodiments, the force distribution may be selected to provide a target balance between levitation, rotational freedom, and induction strength. In certain embodiments, the magnetic force distribution may vary along the axial length of the dual-pipe heat exchanger 102. For example, one region may be optimized for radial support, another for axial positioning, and another for generator interaction.

Referring now to FIG. 7, a graph is shown depicting modeled cumulative efficiency impact associated with successive features of the disclosed cooling and energy recovery system 100. In one embodiment, FIG. 7 illustrates relative projected efficiency improvement as additional system features are incorporated into a baseline dual-pipe heat exchanger configuration. The graph is illustrative and is intended to show one example of how cumulative system performance may improve as features such as magnetic levitation, counter-rotating induction, cryogenic gas injection, liquid nitrogen phase injection, a sealed nitrogen server chassis, hermetic sealed interfaces, and modular containment architecture are integrated into the system 100.

In one modeled example, the baseline dual-pipe system provides an initial cooling and energy recovery platform. Magnetic levitation may reduce parasitic friction losses, counter-rotating magnetic induction may increase energy recapture, cryogenic gas injection may improve cooling and expansion-based power recovery, and liquid nitrogen phase injection may provide increased expansion energy under selected operating conditions. In addition, a sealed nitrogen-pathway server chassis may reduce or eliminate conventional fan energy draw, hermetic wire pass-throughs may preserve enclosure pressure integrity, and modular containment architecture may improve deployment efficiency and reduce leakage or inefficiency.

In one example corresponding to FIG. 7, modeled incremental gains may include approximately fifteen percent associated with magnetic levitation, approximately twenty percent associated with counter-rotating electromagnetic induction, approximately ten percent associated with cryogenic expansion using cold gas, approximately eighteen percent associated with liquid nitrogen flash expansion, approximately twelve percent associated with a sealed nitrogen server chassis, approximately five percent associated with hermetic pass-throughs and pressure preservation, and approximately eight percent associated with modular containment and pre-wired interface architecture. In some modeled implementations, the combined effect may correspond to an overall cumulative efficiency improvement of about eighty-eight percent relative to a baseline air-cooled configuration. These values are illustrative examples derived from modeling assumptions and may vary depending on system size, thermal load, operating environment, working fluid conditions, and component configuration.

In one embodiment, a generalized efficiency relationship corresponding to FIG. 7 may be expressed as:

$$E\_net = E\_base \times ( 1 - ( \sum {S}_{i} / 100 ) )$$

where E_base represents a baseline energy demand of a conventional cooling system and ΣSᵢ represents the sum of modeled savings contributions associated with selected features of the disclosed system 100. This relationship is presented as a generalized example for describing comparative modeled performance and does not limit the invention to a particular thermodynamic formulation.

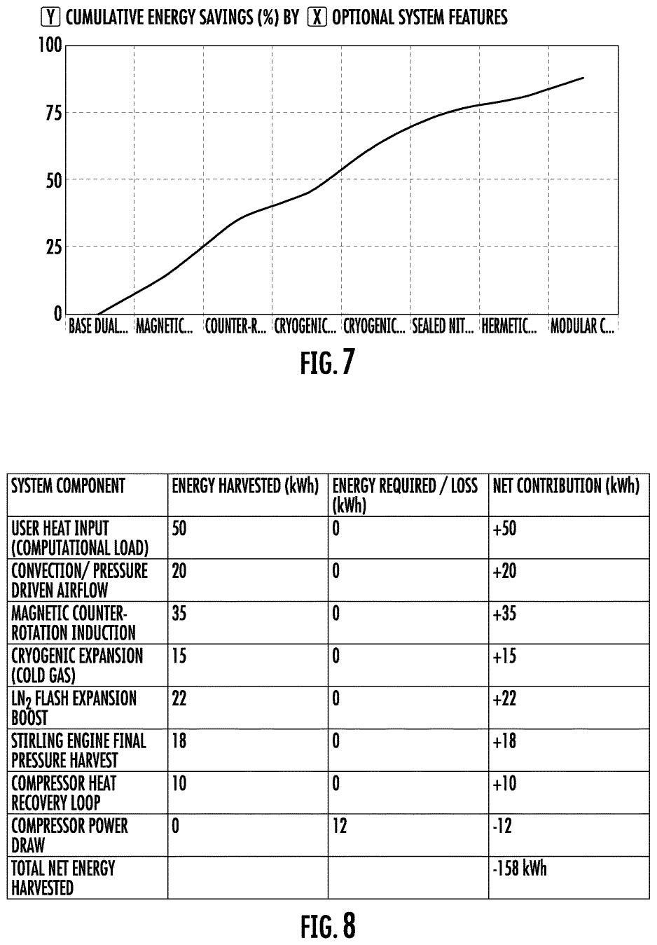

Referring now to FIG. 8, a table or chart is shown depicting an example modeled energy harvest and loss profile for the disclosed cooling and energy recovery system 100 during an operational cycle. In one embodiment, FIG. 8 summarizes example contributions from multiple energy interactions within the system 100, including computational heat input, convection or pressure-driven airflow, magnetic counter-rotation induction, cryogenic expansion, liquid nitrogen flash expansion, Stirling-engine or piston-type pressure recovery, compressor heat recovery, and compressor power draw.

In one illustrative modeled example corresponding to FIG. 8, user heat input associated with computational load contributes about 50 kWh, convection or pressure-driven airflow contributes about 20 kWh, magnetic counter-rotation induction contributes about 35 kWh, cryogenic expansion using cold gas contributes about 15 kWh, liquid nitrogen flash expansion contributes about 22 kWh, Stirling-engine final pressure harvest contributes about 18 kWh, and a compressor heat recovery loop contributes about 10 kWh, while compressor power draw corresponds to a loss of about 12 kWh. Under that example model, total harvested energy is about 170 kWh and net harvested energy after compressor draw is about 158 kWh.

In one embodiment, a generalized system balance relationship corresponding to FIG. 8 may be expressed as:

$$E\_net = \sum ( {H}_{i} ) - \sum ( {L}_{i} )$$

where Hᵢ represents energy harvested from component or subsystem i, and Lᵢ represents energy loss or draw associated with component or subsystem i. In the example model described above, the relationship may be expressed as:

$$E\_net = 170 kWh - 12 kWh = 158 kWh$$

This model is illustrative of one example energy-balance framework for describing multi-stage thermal and electromagnetic energy recapture within the disclosed system 100. Actual harvested energy and losses may vary depending on installation scale, heat load, nitrogen phase behavior, compressor design, and operating conditions.

In some modeled embodiments, the disclosed architecture may recover energy from multiple sources that are ordinarily dissipated or unutilized in conventional cooling architectures. These sources may include computational heat, pressure-driven gas movement, magnetic induction, cryogenic phase expansion, and pressure recovery. FIG. 8 is therefore presented as a comparative and explanatory example and is not intended to limit the invention to a specific energy profile.

Referring now to FIG. 9, a graph is shown depicting comparative annual water use associated with different data center cooling architectures. In one embodiment, FIG. 9 compares a traditional air-cooled system with evaporative cooling, a liquid-to-chip system having a water loop, an AI or LLM workload-related extrapolated water-impact category, and the disclosed nitrogen-based closed-loop system. The graph is intended to illustrate the potential water-use advantage of a nitrogen-based cooling architecture that does not rely on evaporative towers or chilled-water loops for primary cooling operation.

In one example corresponding to FIG. 9, a traditional air plus evaporative cooling system is modeled at approximately 100 million liters of annual water use for a 10 MW data center, a liquid-to-chip water loop system is modeled at approximately 60 million liters annually, and an AI or large language model workload-related extrapolated impact is modeled at approximately 30 million liters annually, while the proposed nitrogen-based system is modeled at approximately zero annual water use during normal closed-loop operation. These values are illustrative and are intended to demonstrate comparative differences in water dependence among cooling architectures.

In one embodiment, the disclosed system 100 achieves substantially waterless cooling by replacing evaporative cooling and water-based liquid loops with a closed-loop nitrogen-based cooling and energy recovery architecture. This can reduce or eliminate reliance on municipal water supply, cooling towers, chilled-water infrastructure, and related water permits. In some deployments, this may provide a strategic advantage in arid regions, water-constrained jurisdictions, remote installations, or regions having regulatory restrictions on industrial water use.

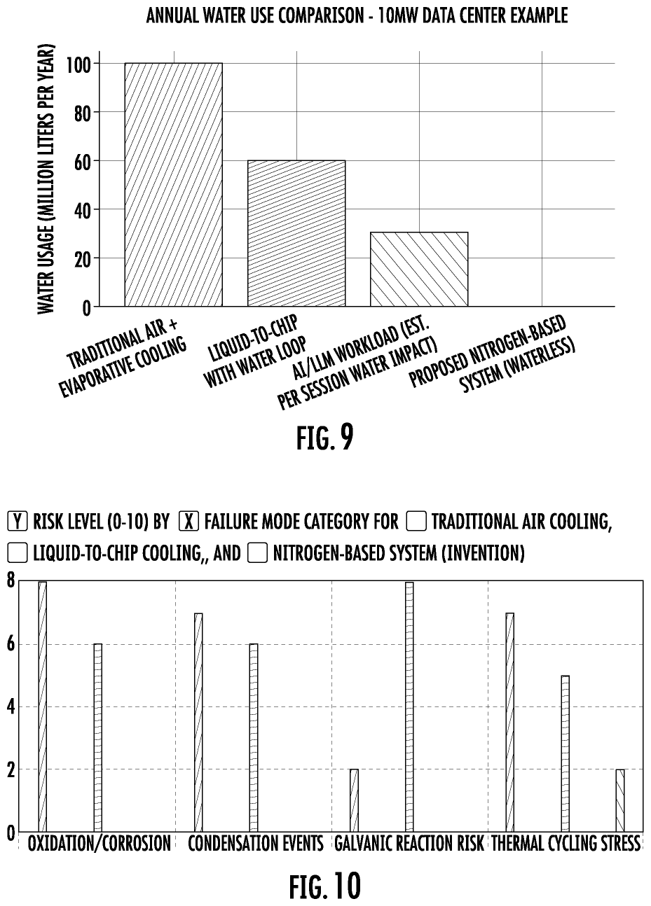

Referring now to FIG. 10, a graph is shown depicting comparative failure-mode risk associated with different cooling environments. In one embodiment, FIG. 10 compares traditional air cooling, liquid-to-chip water-loop cooling, and the disclosed nitrogen-based closed-loop cooling environment with respect to oxidation or corrosion risk, condensation events, galvanic reaction risk, and thermal cycling stress. The graph is intended to illustrate the relative environmental conditions to which electronic equipment may be exposed under different cooling approaches.

In one illustrative comparison corresponding to FIG. 10, traditional air cooling is associated with relatively high oxidation or corrosion exposure, relatively high condensation-event potential, relatively low-to-moderate galvanic reaction risk, and relatively high thermal cycling stress. Liquid-to-chip water-loop systems may reduce some ambient-air effects but may still present relatively high condensation-event potential, relatively elevated galvanic interaction risk due to conductive liquids and dissimilar metals, and continued thermal cycling stress. By contrast, the disclosed nitrogen-based closed-loop system may provide substantially reduced oxidation risk, substantially reduced condensation risk, reduced galvanic reaction exposure, and reduced thermal cycling stress due to the controlled sealed environment.

In one related table based comparison, failure modes may be characterized as follows: oxidation or corrosion may be high risk in traditional air or liquid cooling environments and substantially reduced or eliminated in the nitrogen-based environment; condensation from thermal cycling may be a common failure mode in conventional systems and substantially reduced or eliminated in the disclosed sealed nitrogen environment; reactive galvanic corrosion may be possible in liquid-to-chip systems and substantially reduced or avoided in an inert gas environment; and hardware longevity may be improved relative to conventional cooling environments due to reduced oxidation, moisture exposure, and contamination. These characterizations are comparative and illustrative, and actual outcomes may vary based on equipment design, materials, operating conditions, and maintenance practices.

In operation, heat generated by the heat-generating components 148 of the electronic equipment 146 raises the temperature of the gas circulating within the sealed server chassis 104. The heated gas is directed through the exhaust pipe 108 into the inner pipe 118 of the dual-pipe heat exchanger 102, where the gas drives rotation of the inner screw turbine 124. Simultaneously, cryogenic nitrogen or cooled nitrogen introduced into and/or circulated through the annular space 122 extracts heat through the conductive wall 156 and, in some embodiments, expands to drive the outer turbine 130. The cooled gas exiting the inner pipe 118 is then returned through the supply pipe 106 back to the sealed server chassis 104 to continue the cycle. Electrical energy recovered from rotation of the inner screw turbine 124, the outer turbine 130, and/or the optional assembly 142 may be stored, redistributed, or used to offset system power demand.

In some embodiments, the optional piston power generator or Stirling engine assembly 142 may be fluidly coupled to one or more pressure zones in the annular space 122, the outer pipe 120, or associated fluid reservoirs. In one embodiment, expansion and contraction of nitrogen or another working fluid produces reciprocating motion of a piston, diaphragm, membrane, bellows, or displacer, which may then be mechanically or electromagnetically converted to electrical energy. In another embodiment, the assembly 142 functions as a Stirling-like or pressure-recovery subsystem to improve thermodynamic efficiency and reduce net system energy draw.

In some embodiments, the system 100 may be configured for startup using an external nitrogen source, external compressor, stored cryogenic fluid, external electrical power, or a combination thereof. Once operating, some or all of the recovered energy from the inner screw turbine 124, the outer turbine 130, and/or the assembly 142 may be routed to local storage, batteries, capacitors, a DC bus, facility power conditioning equipment, or direct system loads. Recovered energy may be used to offset operation of controllers, sensors, injectors, valves, pumps, compressors, or other support devices.

The system 100 may be implemented in a wide variety of scales. For example, the inner pipe 118 may be sized for small modular server applications, or may be increased in diameter and length for industrial or large data center installations. Likewise, the outer pipe 120, annular space 122, turbine sizes, injector flow rates, and magnetic support structures may be proportionally scaled. The system 100 may be installed as a single module, multiple parallel modules, multiple serial modules, vertically stacked modules, or distributed modules connected to common manifolds.

In one advantageous embodiment, the system 100 is configured for vertical modular deployment. Because the electronic equipment 146 is cooled in a sealed recirculating architecture rather than by conventional room-scale forced air, the system 100 can support installations in tall structures, high-rise buildings, vertical racks, multi-floor compute facilities, and other vertically arranged environments that are difficult to cool with conventional air-distribution strategies. Multiple dual-pipe heat exchangers 102 may be associated with corresponding sealed server chassis units 104 at different elevations, or one or more centralized nitrogen management subsystems may support multiple equipment levels.

The system 100 may also be used in harsh or contaminated environments. For example, because the cooling environment can be isolated from ambient room air, the system 100 may be deployed in maritime environments, desert environments, industrial environments with elevated particulates, regions with poor air quality, and remote installations where conventional HVAC support is difficult or expensive. In nitrogen-based embodiments, the inert or substantially inert environment around the electronic equipment 146 can reduce oxidation, corrosion, moisture-related failures, and particulate contamination.

In certain embodiments, the disclosed architecture can reduce or eliminate the use of water for cooling. This may provide substantial benefits in jurisdictions where water use is restricted, expensive, or environmentally undesirable. By replacing conventional evaporative cooling towers, chilled-water loops, or liquid-to-chip water infrastructure with a nitrogen-based closed-loop system, the system 100 may reduce facility water demand while still providing thermal management and optional energy recovery.

In some embodiments, the system 100 is configured so that one or more operational parameters converge toward a thermal equilibrium condition in which the recirculating gas within the sealed server chassis 104 and dual-pipe heat exchanger 102 reaches a controlled operating range. Under such conditions, the energy required to maintain circulation and cooling can be reduced relative to conventional room-scale air-conditioning systems. In certain implementations, once stable operation is established, the recovered energy from the turbines and associated energy recovery elements can offset a portion of support system energy demand.

The system 100 may be implemented with a variety of safety and redundancy features. For example, multiple pressure sensors and multiple pressure relief valves 112 may be provided. Redundant controllers 114, redundant injectors 116, and redundant sealed feedthroughs 144 may also be used. Leak-detection logic, emergency venting, automatic inert-gas isolation, component shutdown logic, fire detection logic, oxygen-deficiency safety logic, and facility interlocks may be incorporated depending on installation requirements and applicable codes or standards.

The precise geometry of the components may vary without departing from the invention. For example, the inner screw turbine 124 may be single-start, multi-start, segmented, bladed, cupped, rifled, perforated, or otherwise shaped to respond to gas flow. The outer turbine 130 may be annular, segmented, ring-like, bucketed, finned, paddle-shaped, or otherwise optimized for cryogenic expansion flow. The pipes 118, 120 may be straight, curved, modular, flanged, nested, jacketed, ribbed, or formed in sections. The magnetic levitation assemblies 128, 134 may be fully passive, fully active, or hybrid.

In addition, while the illustrated embodiments show the dual-pipe heat exchanger 102 associated with one sealed server chassis 104, the invention expressly contemplates architectures in which one dual-pipe heat exchanger 102 serves multiple sealed server chassis units 104, or multiple dual-pipe heat exchangers 102 serve a single larger enclosure. Likewise, certain functions may be centralized while others are distributed. For example, nitrogen storage and phase management may be centralized, while localized heat exchanger modules and sealed chassis units are distributed.

The materials, dimensions, pressure ranges, temperatures, rotational speeds, magnetic field strengths, and modeled energy recovery values described herein are exemplary only and may vary depending on the intended installation, facility scale, thermal load, and engineering design targets. Likewise, performance estimates, modeled energy recovery values, and modeled water savings values are illustrative and non-limiting unless expressly recited otherwise.

Although FIGS. 1-10 illustrate one exemplary arrangement of the system 100, the invention is not limited to the specific structural relationships, dimensions, orientations, or component configurations shown. One or more components may be enlarged, reduced, relocated, duplicated, combined, omitted, or replaced while still implementing the disclosed closed-loop cooling and energy recovery principles. Likewise, features described in connection with one figure or one embodiment may be used in combination with features described in connection with another figure or another embodiment.

Accordingly, the disclosed system 100 provides an integrated cooling and energy recovery architecture in which a sealed equipment environment, a dual-pipe heat exchanger, magnetically supported rotating elements, and cryogenic nitrogen-based cooling cooperate to cool heat-generating electronics while reducing losses associated with conventional cooling approaches and optionally reclaiming waste thermal energy. The invention thereby provides a scalable platform for thermal management, power recovery, corrosion reduction, water-use reduction, and vertical deployment flexibility for modern compute environments.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A cooling and energy recovery system for electronic equipment, comprising:
a sealed server chassis configured to house electronic equipment including one or more heat-generating components;
an exhaust pipe and a supply pipe fluidly coupled to the sealed server chassis;
a dual-pipe heat exchanger comprising an inner pipe and an outer pipe disposed radially outward of the inner pipe, the outer pipe and the inner pipe defining an annular space therebetween, the inner pipe having an inlet fluidly coupled to the exhaust pipe and an outlet fluidly coupled to the supply pipe such that gas heated by the electronic equipment circulates from the sealed server chassis, through the inner pipe, and back to the sealed server chassis in a closed-loop or substantially closed-loop flow path;
nitrogen circulating through the annular space and configured to absorb heat from the gas flowing through the inner pipe;
an inner screw turbine disposed within the inner pipe and configured to rotate in response to flow of the gas through the inner pipe;
a generator coupling operatively coupled to the inner screw turbine;
a first electrical generator directly or indirectly operatively associated with the generator coupling and configured to generate electrical energy from rotation of the inner screw turbine; and
an outer turbine disposed within the annular space and configured to rotate in response to flow of the nitrogen circulating through the annular space and expansion of the nitrogen within the annular space.

2. The system of claim 1, wherein the sealed server chassis is configured to define a pressure-maintainable enclosure.

3. The system of claim 1, wherein the gas circulating through the sealed server chassis, the exhaust pipe, the inner pipe, and the supply pipe comprises nitrogen or a nitrogen-rich gas.

4. The system of claim 1, further comprising an inner magnetic levitation assembly configured to levitate, center, support, and/or stabilize the inner screw turbine within the inner pipe.

5. The system of claim 4, wherein the inner magnetic levitation assembly comprises one or more permanent magnets, Halbach arrays, passive magnetic bearings, active magnetic bearings, electromagnets, hybrid magnetic supports, or combinations thereof.

6. The system of claim 1, further comprising an outer magnetic levitation assembly configured to magnetically support and stabilize the outer turbine relative to the inner pipe, the outer pipe, or both.

7. The system of claim 1, wherein the inner pipe includes a conductive wall configured to transfer heat from the gas flowing through the inner pipe to the nitrogen circulating through the annular space.

8. The system of claim 1, further comprising at least one cryogenic nitrogen injector configured to introduce gaseous nitrogen, liquid nitrogen, or a mixed-phase nitrogen flow into the annular space.

9. The system of claim 8, further comprising a controller configured to control operation of the at least one cryogenic nitrogen injector and to regulate circulation of the nitrogen through the annular space based on at least one sensed operating condition.

10. The system of claim 9, wherein the at least one sensed operating condition comprises at least one of temperature, pressure, flow rate, humidity, oxygen concentration, gas composition, vibration, electrical current, or leak detection.

11. The system of claim 1, further comprising a pressure relief valve configured to prevent over-pressurization of at least one of the sealed server chassis, the dual-pipe heat exchanger, the annular space, the supply pipe, or the exhaust pipe.

12. The system of claim 1, wherein the sealed server chassis is configured to operate without conventional internal mechanical fans.

13. A cooling chassis assembly for electronic equipment, comprising:
a sealed server chassis configured to house electronic equipment including one or more heat-generating components;
an exhaust pipe configured to direct heated gas from the sealed server chassis to a dual-pipe heat exchanger;
a supply pipe configured to return cooled gas from the dual-pipe heat exchanger to the sealed server chassis;
at least one internal flow path configured to direct the gas over and around the one or more heat-generating components; and
at least one hermetic wire pass-through configured to permit an electrical line, a control line, a data line, or an optical line to pass through a boundary of the sealed server chassis while maintaining pressure integrity of the sealed server chassis.

14. The cooling chassis assembly of claim 13, wherein the one or more heat-generating components comprise at least one of a CPU, a GPU, a memory module, a storage device, a power supply, or power electronics.

15. The cooling chassis assembly of claim 13, wherein the sealed server chassis comprises a nitrogen-pathway server chassis in which an internal cooling route is integrated into a structure of the sealed server chassis.

16. The cooling chassis assembly of claim 13, wherein the sealed server chassis comprises a containment shell configured to receive an existing server.

17. The cooling chassis assembly of claim 13, wherein the sealed server chassis comprises a modular containment pod having pre-wired internal power and signal interfaces configured to permit insertion and removal of server hardware while maintaining a sealed cooling environment.

18. A method of cooling electronic equipment and recovering energy therefrom, comprising:
housing electronic equipment in a sealed server chassis;
circulating gas heated by the electronic equipment from the sealed server chassis through an inner pipe of a dual-pipe heat exchanger and back to the sealed server chassis in a closed-loop or substantially closed-loop flow path;
circulating nitrogen through an annular space between the inner pipe and an outer pipe of the dual-pipe heat exchanger such that heat is transferred from the gas in the inner pipe to the nitrogen in the annular space;
rotating an inner screw turbine disposed within the inner pipe using flow of the gas through the inner pipe; and
generating electrical energy from rotation of the inner screw turbine.

19. The method of claim 18, further comprising rotating an outer turbine disposed within the annular space using flow of the nitrogen in the annular space and expansion of the nitrogen within the annular space.

20. The method of claim 18, further comprising introducing gaseous nitrogen, liquid nitrogen, or a mixed-phase nitrogen flow into the annular space with at least one cryogenic nitrogen injector based on at least one sensed operating condition.
